(19) United States
(12) Patent Application Publication
(10) Pub. No.: US 2017/0167012 A1
(43) Pub. Date: Jun. 15, 2017

(54) OFF-AXIS MAGNETRON SPUTTERING WITH REAL-TIME REFLECTION HIGH ENERGY ELECTRON DIFFRACTION ANALYSIS

(71) Applicant: Wisconsin Alumni Research Foundation, Madison, WI (US)

(72) Inventors: Chang-Beom Eom, Madison, WI (US); Jacob P. Podkaminer, Madison, WI (US); Jacob J. Patzner, Madison, WI (US)

(21) Appl. No.: 14/963,636

(22) Filed: Dec. 9, 2015

(51) Int. Cl. C23C 14/35; H01J 37/34; C23C 14/34; C23C 14/54

(52) U.S. Cl. CPC C23C 14/355; C23C 14/547; H01J 37/3405; C23C 14/3464; H01J 37/3452

(57) ABSTRACT

Thin film deposition systems with in situ, real-time RHEED monitoring of films deposited via off-axis magnetron sputtering are provided. Also provided are methods of using the systems to grow the films and methods to monitor their growth in real-time. Using the deposition systems, thin films of a sputtered material are grown and monitored in a single vacuum sputtering chamber that houses components of both the magnetron sputtering system and the RHEED system arranged about the substrate onto which the film is grown.

### REFERENCE TO GOVERNMENT RIGHTS

This invention was made with government support under DMR-1234096 awarded by the National Science Foundation. The government has certain rights in the invention.

### BACKGROUND

Atomic layer controlled growth is essential for the understanding and engineering of complex thin film surfaces and heterointerfaces. Molecular beam epitaxy (MBE) and pulsed laser deposition (PLD) growth techniques take advantage of reflection high-energy electron diffraction (RHEED) as an in situ diagnostic tool for monitoring the structure of the surface during deposition, enabling layer-by-layer control at the unit cell and sub unit cell level. The observation of intensity oscillations of the RHEED specular reflection in MBE growth of semiconductors has been exploited to control stoichiometry and growth rate. The RHEED technique was readily adapted to the growth of complex oxides with MBE because the pressure during growth is sufficiently low (<10⁻⁶ Torr) to avoid scattering of the RHEED electron beam. (See, Bozovic, I. & Eckstein, J. N. Analysis of Growing Films of Complex Oxides by Rheed. MRS Bulletin 20, 32-38, doi:doi:10.1557/S0883769400044870 (1995).) Subsequently, RHEED at high pressures (<0.3 Torr) was developed for PLD by Rijnders et al and has been adopted for growing epitaxial oxide films and controlling complex interfaces. (See, Rijnders, G. J. H. M., Koster, G., Blank, D. H. A. & Rogalla, H. In situ monitoring during pulsed laser deposition of complex oxides using reflection high energy electron diffraction under high oxygen pressure. Applied Physics Letters 70, 1888-1890, doi:Doi 10.1063/1.118687 (1997).) However, this important in situ analysis technique has not been applied to real-time monitoring of sputter deposition.

Sputtering offers several challenges that have deterred the inclusion of RHEED analysis during growth, including large magnetic fields around the sputter sources and high background gas pressures. Consequently, the use of in situ, real-time RHEED had not been previously demonstrated with sputtering despite the prominent position of this deposition technique in the growth of many technologically relevant oxide materials.

### SUMMARY

Thin film deposition systems with in situ, real-time RHEED monitoring of films deposited via off-axis magnetron sputtering are provided. Also provided are methods of using the systems to grow the films, methods to monitor their growth in real-time, and methods to align the RHEED electron beam using the magnetron sputtering magnets.

One embodiment of a magnetron sputtering and RHEED system comprises: (a) a substrate having a surface; (b) a first magnetron sputter gun comprising a first magnet assembly and a first layer of target material over the first magnet assembly, the first layer of target material having a first target surface, wherein the surface of the substrate and the first target surface are arranged in an off-axis geometry; (c) a second magnetron sputter gun disposed symmetrically opposite and facing the first magnetron sputter gun, the second magnetron sputter gun comprising a second magnet assembly and a second layer of target material over the second magnet assembly, the second layer of target material having a second target surface, wherein the surface of the substrate and the second target surface are arranged in an off-axis geometry; (d) a RHEED electron gun configured to direct a beam of electrons onto the surface of the substrate at a glancing angle, such that the beam of electrons is directed symmetrically between the first target surface and the second target surface; and (e) a RHEED screen disposed opposite the RHEED electron gun and configured to detect electrons forward scattered from the surface of the substrate.

The systems can be used to deposit and monitor the growth of a film of material on the surface of a substrate by: (i) applying antisymmetric magnetic polarizations to the first magnet assembly and the second magnet assembly; (ii) growing a film of material on the surface of the substrate by sputtering target material from at least one of the first and second layers of target material onto the surface of the substrate via magnetron sputtering; (iii) directing a beam of electrons from the RHEED electron gun onto the surface of the substrate; and (iv) recording a diffraction pattern for electrons reflected from the surface of the substrate onto the RHEED screen, in real-time while the film of material is being grown.

One embodiment of a magnetron sputtering and RHEED system in which the RHEED electron beam can be aligned using the magnets of sputtering system comprises: (a) a first magnetron sputter gun comprising a first magnet assembly comprising: a first central magnet and a first annular magnet disposed around the first central magnet; and a first layer of target material over the first magnet assembly; (b) a second magnetron sputter gun disposed symmetrically opposite and facing the first magnetron sputter gun, the second magnetron sputter gun comprising: a second magnet assembly comprising: a second central magnet and a second annular magnet disposed around the second central magnet; and a second layer of target material over the second magnet assembly; (c) a RHEED electron gun configured to generate a beam of electrons; and (d) a RHEED screen disposed opposite the RHEED electron gun, wherein the RHEED electron gun is configured to direct the beam of electrons toward the RHEED screen.

Using such a system, the RHEED electron beam can be aligned along the x-axis by: (i) applying antisymmetric magnetic polarizations to the first magnet assembly and the second magnet assembly, such that the north poles of the first and second annular magnets face toward the positive x-direction and the north poles of the first and second central magnets face toward the negative x-direction; (ii) directing a beam of electrons from the RHEED electron gun toward the RHEED screen, such that the beam of electrons travels below the first and second layers of target material, but between the plane of the first target surface and the plane of the second target surface, whereby a magnetic field generated by the first and second magnet assemblies deflects the beam of electrons away from the x-direction center of the RHEED screen when the RHEED gun is not properly aligned in the x-direction; (iii) moving the electron gun in the x-direction and monitoring the x-direction displacement of the beam of electrons on the RHEED screen; and (iv) positioning the RHEED gun at a location in the x-direction that minimizes or eliminates the x-direction displacement of the beam of electrons on the RHEED screen.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1A. Top view of a COMSOL simulation showing electron beam deflection in a single off-axis sputtering source geometry.

FIG. 1B. Top view of a COMSOL simulation showing electron beam deflection in a dual off-axis sputtering source geometry that includes two oppositely facing sputtering guns with anti symmetric magnetic polarization.

FIG. 1C. Side view of a COMSOL simulation showing electron beam deflection in the single off-axis sputtering source geometry.

FIG. 1D. Side view of a COMSOL simulation showing electron beam deflection in the dual off-axis sputtering source geometry.

FIG. 2A. Schematic diagram of a growth chamber. The relative orientation between the heater and the sputter gun is shown along with the RHEED setup. Degrees of freedom of the heater and electron gun are shown as the tilt and azimuth and the x, y, and beam tilt respectively.

FIG. 2B. RHEED pattern of a bare SrTiO₃ (STO) substrate in vacuum without the effects from a magnetic field.

FIG. 2C. RHEED pattern of the STO substrate in vacuum with a single sputter source in the off-axis position. Clear tilting of the pattern was observed as well as a reduction in the sharpness of the diffracted spots.

FIG. 2D. RHEED pattern of the STO substrate in 200 mTorr Ar and with the sputter source in the growth position. The tilting was still evident and the scattering due to the Ar gas was very obvious, reducing the specular and diffracted intensities and increasing the background intensity.

FIG. 3A. Specular spot RHEED intensity oscillations during SrRuO₃ (SRO) growth on STO. The actual data is seen with the asymmetric double sigmoidal fit. Clear oscillations were observed corresponding to one unit cell of growth. The inset highlights the first few oscillations where the extended period can be seen due to the termination conversion during SRO growth.

FIG. 3B. The peak to peak period for each unit cell of growth is shown in black with the grey line displaying the exponential decay fit. The fit shows a steady state growth rate of 19.3 s per unit cell after approximately 15 unit cells.

FIG. 4A. Atomic Force Microscope (AFM) image of the SRO surface showing single unit cell steps and incomplete step edges. The inset shows the RHEED image of the SRO with sharp spots after the growth in vacuum with the sputter source in position causing the tilting of the pattern.

FIG. 4B. Out of plane X-Ray Diffraction (XRD) scan showing the relationship between the (002) peak of the SRO and STO. Distinct Kiessig fringes are present indicating the interface and surface were both sharp and smooth.

FIG. 4C. The X-Ray Reflectivity (XRR) data shown in black with the fitted data in grey provide an accurate thickness estimation, and indicate the high quality of the surface and interface. The fit gives an estimated total thickness of 27.1 nm.

FIG. 5A. Two-dimensional cross-section showing the magnetic field close to the sample for the single gun off-axis geometry. The magnetic field lines close to the sample are pointing nearly vertical resulting in a lateral bending of the electron beam.

FIG. 5B. Two-dimensional cross-section showing the magnetic field close to the sample for the dual gun off-axis geometry with antisymmetric magnet polarization. The magnitude of the magnetic field close to the sample is approximately a factor of 10 weaker than for the single gun off-axis geometry. The field lines are also horizontal, resulting in only a small bending in the y-direction.

FIG. 6A. Top view of a COMSOL simulation showing electron beam deflection in a dual off-axis sputtering source geometry that includes two oppositely facing sputtering guns with symmetric magnetic polarization. This results in much larger magnetic fields close to the sample (approximately 43 Gauss) when compared with the antisymmetric arrangement (approximately 10 Gauss as seen in FIG. 1A) which results in a large bending of the electron beam away from the RHEED screen.

FIG. 6B. Side view of a COMSOL simulation showing electron beam deflection in a dual off-axis sputtering source geometry that includes two oppositely facing sputtering guns with symmetric magnetic polarization.

FIG. 7A. The RHEED image of a SrTiO₃ substrate in a 75 mTorr O₂ deposition environment. The electron gun power was held constant and the only difference was the gas species.

FIG. 7B. The RHEED image of a SrTiO₃ substrate in a 75 mTorr Ar environment. The electron gun power was held constant and the only difference was the gas species. In FIG. 7B, the background intensity was higher, showing more diffuse scattering with respect to FIG. 7A, which demonstrates the difference in the scattering cross-section between the two gas species. This directly impacts the observable dynamic range and makes smaller signals harder to detect in the Ar environment.

FIG. 8A. RHEED image showing specular spot intensity oscillations during La_{0.7}Sr_{0.3}MnO₃ growth on an SrTiO₃ substrate with clear oscillations, indicating a layer-by-layer growth mode. The inset shows a diffraction pattern of the film after growth in vacuum with the magnetic field present, sharp spots with some streaking is seen, indicating a flat 2-dimensional surface.

FIG. 8B. RHEED image showing specular spot intensity oscillations during LaAlO₃ growth on a SrTiO₃ substrate, where the specular spot intensity oscillations get weak very quickly, but then are maintained out to greater than 10 oscillations. The inset shows a zoomed in region to better display the oscillations with low intensity. The large amount of noise is a result of the diffuse scattering from Ar gas screening the low intensity RHEED pattern.

FIG. 9A. Side view of a COMSOL simulation showing electron beam deflection in a four gun (two gun pair) off-axis sputtering source geometry that includes two pairs of oppositely facing sputtering guns with antisymmetric magnetic polarization for each of the pairs.

FIG. 9B. Top view of a COMSOL simulation showing electron beam deflection in the four gun off-axis sputtering source geometry.

FIG. 10A. Two-dimensional cross-section showing the magnetic field close to the sample for the dual gun off-axis geometry with antisymmetric polarization of the magnets. The magnitude of the magnetic field close to the sample is weaker than for the dual gun off-axis geometry with symmetric polarization (see, FIG. 10B). The field lines are also horizontal, resulting in only a small bending in the y-direction.

FIG. 10B. Two-dimensional cross-section showing the magnetic field close to the sample for the dual gun off-axis geometry with symmetric polarization of the magnets.

FIG. 11A. RHEED pattern of a bare STO substrate in vacuum without the effects from a magnetic field.

FIG. 11B. RHEED pattern of the STO substrate in vacuum with a single sputter source in the off-axis position. Clear tilting of the pattern was observed as well as a reduction in the sharpness of the diffracted spots.

FIG. 11C. RHEED pattern of the STO substrate in vacuum with a dual sputter source in the off-axis position.

FIG. 11D. RHEED pattern of an SrRuO₃ film deposited on the STO substrate in vacuum with the dual sputter source in the off-axis position.

FIG. 12. Specular spot RHEED intensity oscillations during SrRuO₃ film growth on the STO substrate.

FIG. 13A. Top view of a COMSOL simulation showing electron beam deflection in a dual off-axis sputtering source geometry that includes two oppositely facing sputtering guns with antisymmetric magnetic polarization, including annular magnets having their north poles facing the negative x-direction and central magnets having their north poles facing the positive x-direction. In the embodiment depicted here, the incident electron beam of offset in the positive x-direction.

FIG. 13B. Top view of a COMSOL simulation showing electron beam deflection in a dual off-axis sputtering source geometry that includes two oppositely facing sputtering guns with antisymmetric magnetic polarization, including annular magnets having their north poles facing the positive x-direction and central magnets having their north poles facing the negative x-direction. In the embodiment depicted here, the incident electron beam of offset in the positive x-direction.

FIG. 13C. Top view of a COMSOL simulation showing electron beam deflection in a dual off-axis sputtering source geometry that includes two oppositely facing sputtering guns with antisymmetric magnetic polarization, including annular magnets having their north poles facing the negative x-direction and central magnets having their north poles facing the positive x-direction. In the embodiment depicted here, the incident electron beam of offset in the negative x-direction.

FIG. 13D. Top view of a COMSOL simulation showing electron beam deflection in a dual off-axis sputtering source geometry that includes two oppositely facing sputtering guns with antisymmetric magnetic polarization, including annular magnets having their north poles facing the positive x-direction and central magnets having their north poles facing the negative x-direction. In the embodiment depicted here, the incident electron beam of offset in the negative x-direction.

### DETAILED DESCRIPTION

Thin film deposition systems with in situ, real-time RHEED monitoring of films deposited via off-axis magnetron sputtering are provided. Also provided are methods of using the systems to grow the films and methods to monitor their growth in real-time. The use of in situ, real-time RHEED analysis allows for the rapid optimization of growth parameters and control of growth rates by making it possible to compare film quality and roughness throughout the on-going growth process. In addition, it enhances the reproducibility of the interfaces and provides for superlattice growth by allowing for real-time digital control of the exact thicknesses of each layer. Moreover, analysis of in situ RHEED intensities can provide fundamental information on epitaxial growth mechanisms that are currently unknown for many thin film systems deposited by the magnetron sputtering technique.

Using the deposition systems, thin films of a sputtered material are grown and monitored in a single vacuum sputtering chamber that houses components of both the magnetron sputtering system and the RHEED system arranged about the substrate onto which the film is grown.

The substrate has a surface, which is typically a planar or substantially planar surface, onto which sputtered material is deposited to form a film. The substrate may be mounted on a substrate holder that allows the substrate to be manipulated and rotated within the sputtering chamber. The system may optionally include a heater for heating the substrate holder and substrate.

The magnetron sputtering system includes at least one pair of magnetron sputtering guns, each sputtering gun including a layer of target material (“a target”) having a target surface from which the target material will be sputtered. The target is mounted on a target holder, which is typically a cooled (for example, water-cooled) holder. The target and target holder are disposed over a magnet assembly. The magnet assembly may include one or more magnets having various geometries, provided that they include neighboring north and south polarities. In some embodiments of the magnetron sputtering systems, the magnet assembly comprises a planar magnet assembly with an inner central magnet surrounded by an outer, annular magnet.

The targets can be comprised of a wide variety of materials, including magnetic and non-magnetic materials. Such materials include metals, metal alloys, oxides, including complex oxides, ceramics, superconducting materials, and ferromagnetic materials. The targets can comprise the same target materials, or can be comprised of different target materials.

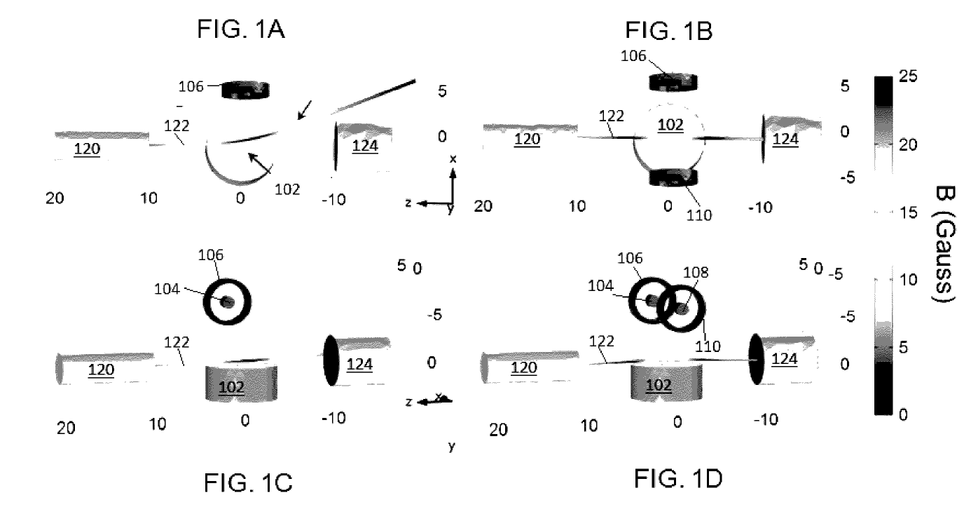

The first and second magnetron sputtering guns in a magnetron sputtering gun pair are disposed symmetrically opposite with their target surfaces facing one another in an off-axis geometry. In the off-axis geometries the target surfaces are oriented at an angle greater than 0° (for example, greater than 20°, greater than 45°, or greater than 80°) with respect to the substrate surface. In some embodiments, the first and second magnetron sputtering guns are disposed in a 90° off-axis geometry. In a 90° off-axis geometry, the targets are disposed over and to the side of the substrate, such that the target surfaces are oriented at a right angle with respect to the substrate surface. Magnetron sputtering guns are disposed symmetrically opposite one another when they are spaced equi-distant from the central axis running normal to the substrate surface. This is illustrated schematically in FIGS. 1B and 1D, which show a top view and side view, respectively, of a combined magnetron sputtering and RHEED system. For simplicity, only the magnets of the sputtering guns are shown. The system includes a substrate 102 disposed centrally below a pair of planar magnet assemblies. The first planar magnet assembly comprises a first central magnet 104 and a first annular magnet 106. Disposed symmetrically opposite the first planar magnet assembly is a second planar magnet assembly comprising a second central magnet 108 and a second annular magnet 110.

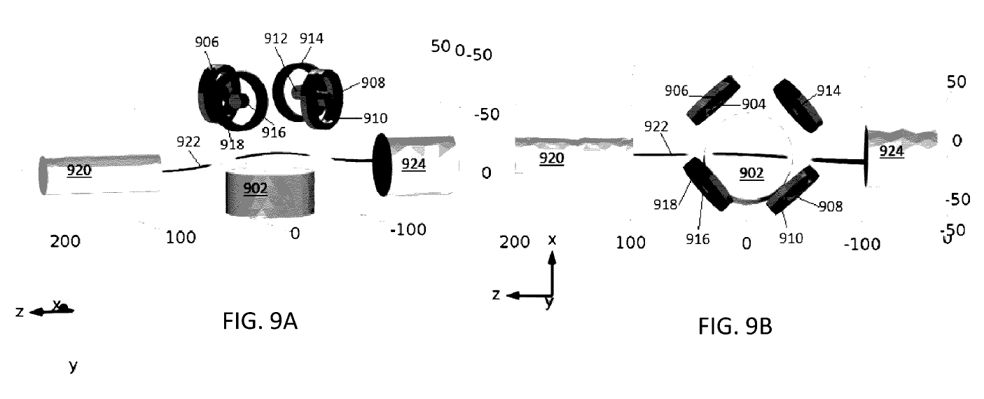

Some embodiments of the magnetron sputtering system include more than one pair of magnetron sputtering guns. For example, two pairs of magnetron sputtering guns can be used. A system comprising two pairs of magnetron sputtering guns, wherein the magnetron sputtering guns in each pair are disposed symmetrically opposite one another with their target surfaces facing one another in a 90° off-axis geometry is shown in FIGS. 9A and 9B. Here, again, only the magnet assemblies of the sputtering guns are shown for simplicity. The system includes a substrate 902 disposed centrally below two pairs of planar magnet assemblies. The first planar magnet assembly comprises a first central magnet 904 and a first annular magnet 906. Disposed symmetrically opposite the first planar magnet assembly is a second planar magnet assembly comprising a second central magnet 908 and a second annular magnet 910. The third planar magnet assembly comprises a third central magnet 912 and a third annular magnet 914. Disposed symmetrically opposite the third planar magnet assembly is a fourth planar magnet assembly comprising a fourth central magnet 916 and a fourth annular magnet 918. A RHEED electron gun 920, an electron beam directed at substrate 902, and a RHEED screen 924 are also shown.

Because the antisymmetric magnetic polarization of the magnets dramatically reduces the deflection of the RHEED electron beam when the system is in operation, the distance between the target surface of each sputtering gun and the surface of the substrate, as measured from the center of the target to the center of the substrate, can be quite short. By way of illustration, in some embodiments of the systems the distance between the target surface and the substrate surface is no greater than 10 cm. This includes embodiments in which said distance is no greater than 8 cm, no greater than 5 cm, and no greater than 3 cm.

The RHEED system includes an electron gun disposed on one side of the substrate and an electron detection screen disposed opposite the electron gun on the other side of the substrate. The electron gun generates electrons and focuses them into a narrow, well-defined beam. It includes an electron source, which may be a filament through which a current passes, resulting in the ejection of electrons, and focusing optics that focus the electrons into an electron beam. The electron gun further includes a housing, at least a portion of which may extend into the interior of the sputtering chamber, along the path of the electron beam. The housing is optionally equipped with a differential pumping stage. As shown in FIGS. 1B and 1D, the RHEED electron gun 120 is configured to direct the beam of electrons 122 onto the surface of substrate 102 at a glancing angle. The glancing angle may be, for example, ≦5°, where the glancing angle is the angle between the incident electron beam and the plane of the substrate surface. In some embodiments glancing angles of ≦2°, ≦1°, or ≦0.5° are used. A RHEED screen 124, which is typically a phosphor screen, is disposed opposite and facing electron gun 120, such that electrons from electron beam 122 that are forward scattered from the surface of substrate 102 form a diffraction pattern on the screen. The electron gun is also configured such that the electron beam is directed symmetrically between the first target surface and the second target surface. This is illustrated for a magnetron sputtering system having only a single pair of magnetron sputtering guns in FIG. 1B, wherein the RHEED electron gun is configured to direct the beam of electrons onto the surface of the substrate, such that the beam is centered below and between the plane of the first target surface and the plane of the second target surface, equi-distance from both surfaces. In a magnetron sputtering system that has two pairs of magnetron sputtering guns, the electron gun is configured to direct the beam of electrons onto the surface, such that the beam of electrons goes through a central axis about which the first, second, third and fourth target surfaces are symmetrically arranged, passing below and between the first and third targets and below and between the second and fourth targets, as illustrated in FIG. 9.

Although not shown in FIG. 1 or 9, the thin film deposition systems may further include various components conventionally found in high vacuum magnetron sputtering and RHEED systems. These include, but are not limited to, pumps and their associated valves for evacuating the sputtering chamber, flow controllers for introducing and controlling the flow of gases into the sputtering chamber, pressure and/or temperature gauges, power supplies for the magnetron sputtering and RHEED systems, rotational and translational stages for manipulating the positions of the substrate, the sputter guns and/or the RHEED electron gun and screen in the chamber, and cooling water lines.

When the system is in operation, the growth of the thin film on a substrate surface can be monitored and controlled in real-time, as the film is being deposited by magnetron sputtering.

Magnetron sputtering is a plasma coating process whereby sputtering material is ejected from the surface of a target as the result of the bombardment of the target with ions. During sputtering, the vacuum chamber is filled with an inert gas. By applying a high voltage, a plasma discharge is created and ions are accelerated into the target surface. These ions eject target material from the target surface (sputtering). This sputtered material is then deposited onto the surface of the substrate to be coated to form a layer of the target material. The magnet assemblies in the magnetron sputtering guns create magnetic fields that keep the plasma in front of the target, intensifying the bombardment of ions.

During sputtering, all or fewer than all of the magnetron sputtering guns can be used. For example, for a system comprising a single pair of magnetron sputtering guns, only one gun need be used to form the deposited film. However, it may be advantageous to use more than one target during film deposition. For example, if layers of different materials are to be deposited, one can use targets comprising different target materials that are sputtered sequentially. Alternatively, if a layer of mixed material is to be deposited, one can use targets comprising different target materials that are sputtered simultaneously. Optionally, the substrate can be rotated about its central axis to provide a more uniform distribution of the sputtered material on the substrate surface.

Argon is commonly used as the inert gas during sputtering. However, other inert and non-inert gases can be used. For example, for reactive magnetron sputtering, a reactive gas, such as oxygen, can be introduced along with an inert gas. Magnetron sputtering is characterized by high gas pressures in the sputtering chamber during film growth. This is one reason that in situ RHEED analysis has conventionally been viewed as inconsistent with magnetron sputtering—particularly off-axis magnetron sputtering where the sputtering targets must be kept in close proximity to the substrate and the RHEED electron beam. By way of illustration, the deposition of the target materials onto the substrate can be conducted at chamber pressures of 100 mTorr or higher. This includes depositions that are carried out at chamber pressures of 200 mTorr or higher, 300 mTorr or higher, and 500 mTorr or higher.

RHEED is an analytical tool for monitoring thin films. It is very sensitive to changes in surface structure and morphology. As such, RHEED allows the growth rate of thin films on the surface to be monitored by analyzing periodic variations in the RHEED intensity during growth. In RHEED, a beam of electrons with high kinetic energies (typically in the 5-100 keV regime) and low incident angles are reflected from the surface of the substrate and are scattered from the top surface layer of the substrate. The scattered electrons, which undergo constructive interference, strike the RHEED screen where they form a characteristic RHEED pattern based on the morphology and roughness of the substrate surface. Because the RHEED intensity depends on the film roughness, the growth of a film on the substrate leads to characteristic intensity oscillations during film growth, where the oscillations correspond to the completion of individual monolayers.

Unfortunately, if a RHEED system were incorporated into a conventional off-axis magnetron sputtering system having a single magnetron sputtering gun, the electron beam would be grossly defected and the RHEED pattern would become tilted or otherwise distorted on the RHEED screen. This distortion is illustrated in the Examples below.

The present systems address the problem of electron beam deflection by applying an antisymmetric magnetic polarization to the opposing magnet assemblies in the magnet assembly pairs. As a result of the antisymmetric magnetic polarization, the magnetic field lines at the surface of the growth substrate are parallel with the substrate surface, or nearly so. In contrast, a sputtering system that has only a single magnet assembly, or that has a magnet assembly pair in which the opposing magnet assemblies have a symmetric magnetic polarization, produces magnetic field lines at the surface of the growth substrate that run perpendicular to the substrate surface, or nearly so. In addition, relative to a symmetric magnetic polarization, an antisymmetric polarization produces a lower magnetic field strength at the surface of the substrate.

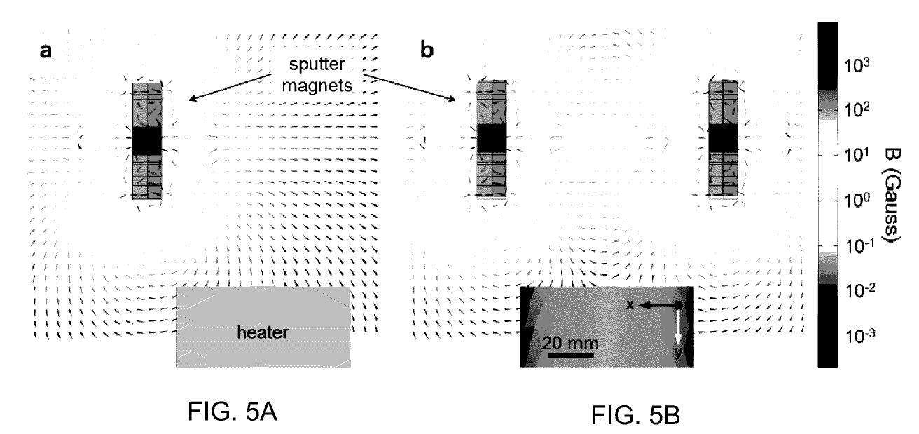

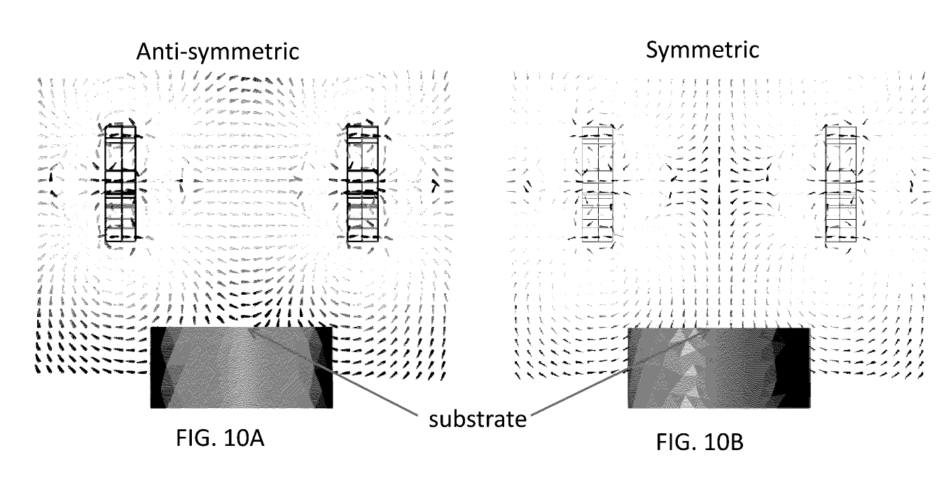

These effects are illustrated in FIGS. 5A and 5B and in FIGS. 10A and 10B. FIG. 5A is a two-dimensional cross-sectional view of the magnetic field close to a substrate for a sputtering system having only a single magnetron sputtering gun in an off-axis geometry. FIG. 5B is a two-dimensional cross-sectional view of the magnetic field close to a substrate for a sputtering system having a pair of symmetrically opposing magnetron sputtering guns with antisymmetric polarization in an off-axis geometry. In the single gun system, the magnetic field lines close to the substrate are pointing nearly vertical, resulting in a lateral bending of the electron beam in the xz-plane (FIG. 1A). Moving upward along the vertical axis, the magnetic field lines transition to horizontal, which can cause a vertical bending of the electron beam as well.

In contrast, in the dual gun, antisymmetric system, the magnetic field lines close of the substrate are horizontal and the magnitude of the magnetic field is weaker, resulting only in a very minor bending of the electron beam in the y-direction (FIG. 1D).

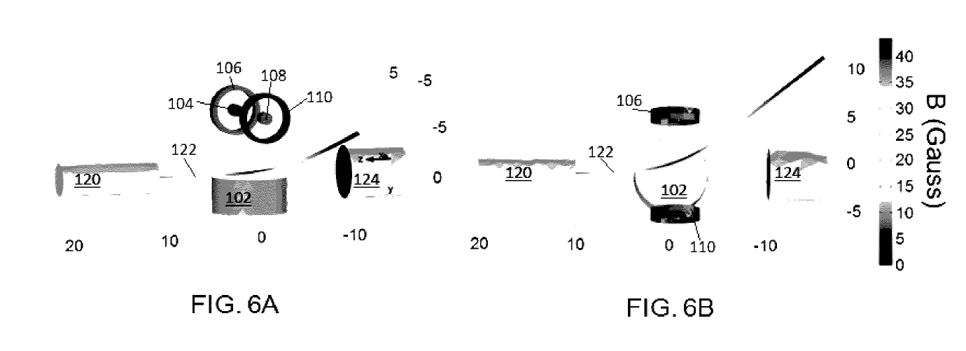

FIG. 10A is another two-dimensional cross-sectional view of the magnetic field close to a substrate for a sputtering system having a pair of opposing magnetron sputtering guns with antisymmetric polarization in an off-axis geometry. FIG. 10B is a two-dimensional cross-sectional view of the magnetic field close to a substrate for a sputtering system having a pair of opposing magnetron sputtering guns with symmetric polarization in an off-axis geometry. In the dual gun symmetric system, the magnetic field lines close to the substrate are pointing nearly vertical, resulting in a lateral bending of the electron beam in the y-direction and in the xz-plane (FIGS. 6A and 6B). In contrast, in the dual gun, antisymmetric system, the magnetic field lines close of the substrate are horizontal and the magnitude of the magnetic field is weaker, resulting only in a very minor bending of the electron beam in the y-direction (FIG. 1D).

The result, which is shown in FIGS. 1B and 1D, is that magnet assemblies having antisymmetric polarizations greatly reduce the electron beam deflection compared to either single magnetron sputtering gun systems or dual magnetron sputtering gun system that employ a symmetric magnetic polarization. Notably, this striking reduction in electron beam deflection can be accomplished without the need for magnetic shielding around the incident electron beam. It should be noted that the magnetic fields of the magnet assemblies in FIGS. 1B and 1D could be flipped, such that the bend in the electron beam was directed toward the substrate surface. However, the path of the electron beam is more easily seen using the polarization shown in FIGS. 1B and 1D.

Beam deflection can be reduced in a similar manner using multiple pairs of magnetron sputtering guns, as illustrated in FIGS. 9A and 9B, which show a COMSOL simulation showing electron beam deflection in a four gun (two gun pair) off-axis sputtering source geometry that includes two pairs of oppositely facing sputtering guns with antisymmetric magnetic polarization for each of the pairs. As illustrated in these figures, the electron beam 922 goes straight along the z direction and has a double deflection in the y direction. The net result is that the electron beam is deflected less severely that it would be in a single-gun set-up or a dual gun set-up using symmetric magnetic polarization. Again, the magnetic fields of the magnet assemblies in FIGS. 9A and 9B could be flipped, such that the bend in the electron beam was directed toward the substrate surface. However, the path of electron beam is more easily seen using the polarization shown in FIGS. 9A and 9B.

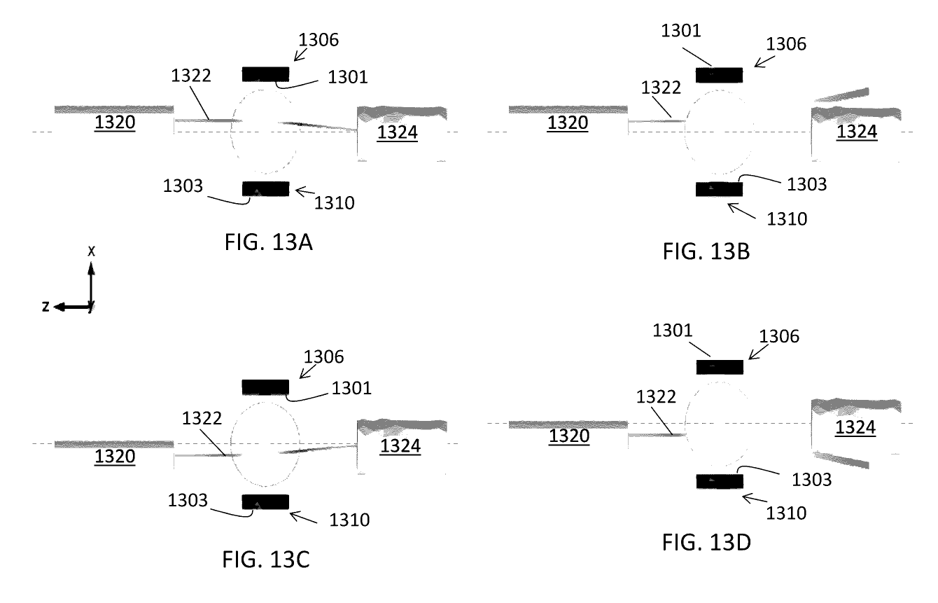

In addition to enabling real-time, in situ RHEED analysis of sputtered films, the antisymmetric magnetic polarization of the magnet assemblies in the system makes it possible to operate with a RHEED electron beam that is not perfectly aligned between the magnet assemblies because the antisymmetric magnet assemblies function to automatically center a misaligned electron beam. This is illustrated in FIG. 13A, which shows a COMSOL simulation of a misaligned electron beam directed into a sputtering chamber with a dual off-axis sputtering gun geometry. As shown in the figure, the incident electron beam 1322 from RHEED gun 1320 is slightly offset from center along the positive x-axis. However, for the antisymmetric magnetic field polarization shown in FIG. 13A, in which the north poles 1301, 1303 of the annular magnets 1306, 1310 face in the negative x-direction and the north poles of the central magnets (not visible in this view) face in the positive x-direction, the effect of the magnetic field on electron beam 1322 is such that the beam is directed back towards the horizontal (x-direction) center of the RHEED screen 1324. This effect is desirable when the RHEED electron gun is not, or cannot be, perfectly centered, because the magnetic field generated by the magnet assembly pair automatically centers misaligned electron beam 1322 as it moves between the two magnet assemblies toward RHEED screen 1324. As shown in FIG. 13C, this centering effect is symmetric around the center point, such that the electron beam will be centered by the magnetic field, regardless of the direction of the x-offset of the beam.

By flipping the polarization of the magnets in the magnet assemblies, such that the north poles 1301, 1303 of the annular magnets 1306, 1310 face in the positive x-direction and the north poles of the central magnets (not visible in this view) face in the negative x-direction, the deflection electron beam 1322 away from the horizontal center of RHEED screen 1324 can be exacerbated, as shown in FIG. 13B. While this is disadvantageous for collecting RHEED data, it can be useful for aligning the electron beam prior to film deposition. If the position of RHEED electron gun 1320 is adjustable along the x-direction, using the antisymmetric magnetic polarization shown in FIG. 13B would allow the user to find the centered position of the electron beam with high certainty, by moving the electron gun along the x-axis to identify the position that minimizes or eliminates the x-axis displacement of the electron beam on the RHEED screen. As shown in FIG. 13D, this beam deflection enhancing effect is symmetric around the center point, such that the electron beam will be deflected by the magnetic field, regardless of the direction of the x-offset of the beam. As used herein, the x-direction is defined as shown in FIG. 13, wherein the z-direction (z-axis) runs normal to the plane of the RHEED screen and the x-direction (x-axis) runs perpendicular to the z-direction. The positive x-direction is represented by the arrow pointing upward in the figure.

### Examples

### Example 1

This example demonstrates digital control of sputter deposition using in situ high-pressure RHEED by applying this technique to the widely studied model oxide system, SrRuO₃ (SRO). During 90° off-axis sputtering of SRO films strong specular spot oscillations extending beyond 50 unit cells were observed. This allowed the identification of the growth mode as layer-by-layer and established the ability to have unit cell control during sputter growth. Similar results were seen during the growth of perovskites La_{0.7}Sr_{0.3}MnO₃ (LSMO) and LaAlO₃ (LAO), confirming that this approach can be universally applied to sputter deposition of other materials.

Results

In the RHEED geometry, an electron beam of 10-35 kV energies is directed toward the sample at grazing incidence and the diffracted beam is recorded on a phosphor screen; the grazing geometry ensures minimal interference with the ongoing deposition fluxes. Magnetic fields produced by sputter sources will deflect the electron beam from its original trajectory, making it difficult to observe the diffraction pattern. As expected, this deflection is very sensitive to the magnets' proximity and orientation with respect to the beam, so small changes in the position of the sputter source can have large effects on the electron beam.

To predict the effect of the magnetic field on the electron beam trajectory, COMSOL (COMSOL Multiphysics® version 5, AC/DC and Particle Tracing Modules) was used to model the magnetic field produced by the magnets in a 2-inch planar magnetron sputter gun oriented in the 90° off-axis geometry, and simulate the beam trajectory when passing through the magnetic field. A 3-dimensional representation of the growth geometry can be seen in FIGS. 1A and 1C (top and side view, respectively). From the simulation, it can be seen that the deflection due to the magnetic field was sufficient to completely miss the 55 mm phosphor screen. The color gradient along the beam shows the magnitude of the magnetic field that the electrons encountered traveling from the gun to the screen. The simulation used actual working distances between the electron gun, phosphor screen, heater block, and magnets in the sputter source in the chamber geometry, including the 35 kV beam voltage used experimentally. Further details related to the model can be found in the “Methods” section, and a cross-sectional view of the magnetic field near the sample is shown in FIG. 5. FIG. 5A shows the field for a single off-axis gun geometry. FIG. 5B shows the field for two-gun geometry.

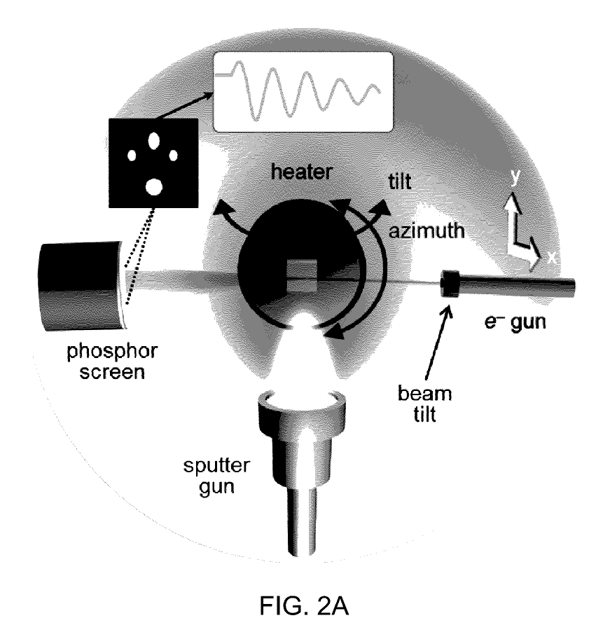

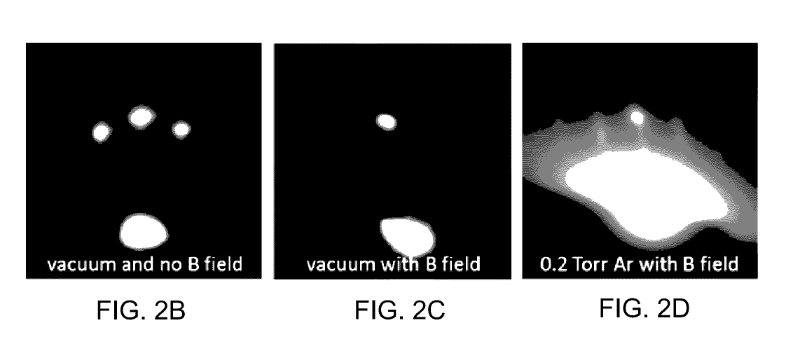

These simulations facilitate the understanding and prediction of the deflection of the electron beam and make it possible to optimize the chamber's geometry by adjusting the position and tilt of the electron gun and sample so that the electrons can arrive on the sample at grazing incidence and subsequently strike the phosphor screen. FIG. 2A shows a schematic diagram of the chamber setup with the adjustments discussed above. These adjustments were sufficient to keep the RHEED diffraction pattern on the edge of the phosphor screen during deposition; however, the power of COMSOL was also used to find a geometry that would minimize the deflection of the electron beam for future chamber designs. The optimal layout found can be seen in FIGS. 1B and 1D which shows the 3-D model of 2 off-axis sputter guns facing each other on opposite sides of the heater. An important factor is the antisymmetric magnetic polarity of the sputter guns. This minimizes the strength of the magnetic field affected by the electron beam, as seen by the predominantly blue color of the beam, where blue represents lower magnetic field. This resulted in dramatically lower deflection of the beam, and limited deflection to only the y-direction. The effect of the symmetric magnetic geometry on the electron beam is shown in FIG. 6. There are multiple interesting implications that accompany this finding. First, this is not only an important way to mitigate the magnetic fields during single target sputtering by simply having only one of the two guns in use, but is also desirable for the growth of complex heterostructures or superlattices that would require two sputter sources. Second, it has been shown that an antisymmetric sputter geometry improves film uniformity over large areas. The antisymmetric magnets eliminate the confined magnetic field created by a symmetric setup, which avoids the resputtering of deposited materials, making scalability more feasible. (See, Newman, N., Cole, B. F., Garrison, S. M., Char, K. & Taber, R. C. Double gun off-axis sputtering of large area YBa2Cu3O7-d superconducting films for microwave applications. IEEE Transactions on Magnetics 27, 1276-1279, doi:10.1109/20.133417 (1991).)

While the 2 gun geometry is the preferred layout, the results reported here were obtained using the single gun (with a dummy magnet assembly completing the magnetic assembly pair) method due to spatial constraints in the growth chamber. The schematic of the system showing the sputtering, RHEED, and heater setup with the relevant degrees of freedom is seen in FIG. 2A. The effects of the magnetron's magnetic field on the RHEED pattern of a SrTiO₃ (STO) substrate can be seen in FIGS. 2B, 2C, and 2D. FIG. 2B is a RHEED image of a bare STO substrate in vacuum in the absence of magnetic fields; clear spots and Kikuchi lines can be observed. FIG. 2B shows the RHEED pattern of the same STO substrate in vacuum with the sputter gun present in the off-axis growth position; the field caused the diffraction pattern to tilt and the spots to become irregularly shaped. FIG. 2C shows the substrate diffraction pattern in the presence of 200 mTorr of Ar and the magnetic field; the background gas led to an increased diffuse background intensity in the RHEED image. While background gas pressures can be similar for sputtering and high-pressure PLD (˜0.2 Torr), Ar has a higher scattering cross-section for electrons compared with oxygen (˜4 times larger), resulting in a relatively higher diffuse background intensity.

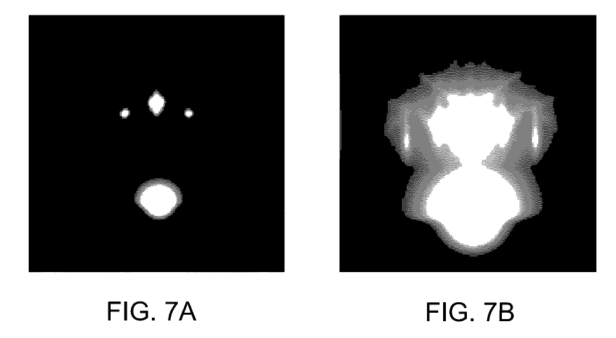

This scattering due to the higher pressures and scattering cross-section decreased the diffraction intensity while increasing the overall background signal observed on the phosphor screen, reducing the total dynamic range that could be measured. This effect is further demonstrated in FIG. 7A and FIG. 7B. The scattering can be mitigated by increasing the energy of the electrons and by decreasing the distance between the aperture of the beam source and the phosphor screen. As previously mentioned, the beam energy was 35 keV (the upper limit of the source). The working distance was 18 cm although shorter distances are recommended. However, it should be noted that higher energies led to a larger Ewald's sphere. Both the larger Ewald's sphere and the shorter working distance led to a contraction of the RHEED pattern spacing and subsequently a decrease in the lateral resolution of the diffracted spots. Thus, further optimization of the beam energy and working distance can be done for each individual chamber design. Additionally, sputtering is an energetic process with a relatively large plasma, so care should be taken to avoid coating the phosphor screen.

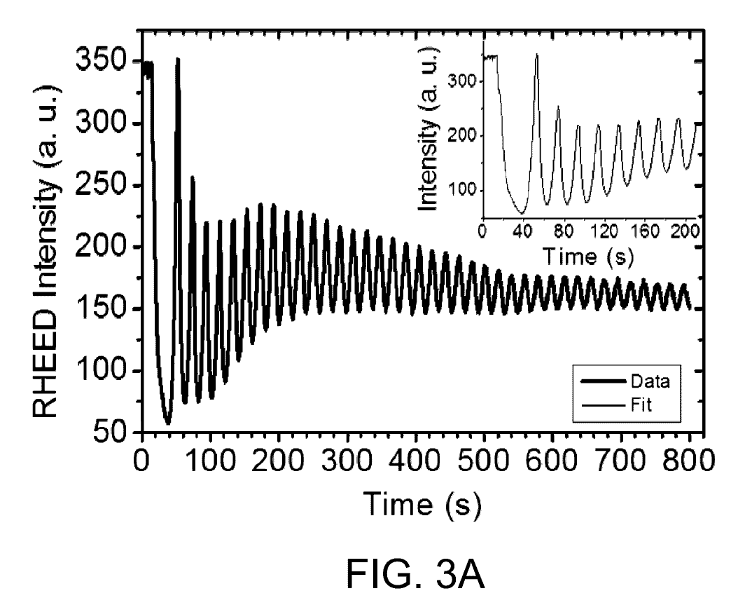

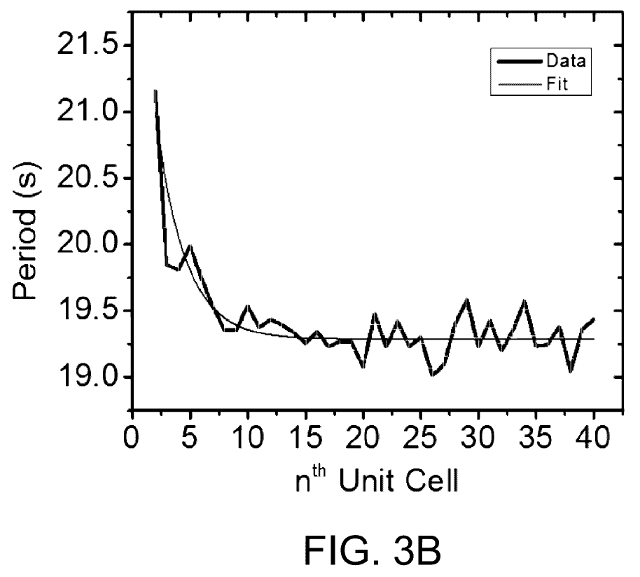

Using the magnetic field modeling and the high pressure considerations discussed above, SRO thin films were grown on STO substrates in the single gun 90° off-axis geometry with in situ RHEED. The growth mode was identified and RHEED oscillations were observed during the deposition, as seen in FIG. 3A. The intensity of the (0,0) specular spot was monitored as a function of time during the deposition and it can be clearly seen by the oscillations in FIG. 3A that the film grew in the layer-by-layer mode with oscillations that extended out to greater than 50 clear intensity oscillations, each corresponding to a single unit cell of deposition (only shown out to 40 here to be able to distinguish peaks). This allows for the ability to have exact unit cell control of the growth during sputter deposition, which has never previously been demonstrated for any epitaxial sputter growth.

Furthermore, the extended oscillations are of particular interest when comparing the sputter grown SRO to that which is observed in PLD grown SRO. In PLD grown films, it has been shown that the growth mode of SRO begins as layer-by-layer growth and transitions to step flow growth after several unit cells. (See, Choi, J., Eom, C. B., Rijnders, G., Rogalla, H. & Blank, D. H. A. Growth mode transition from layer-by-layer to step flow during the growth of heteroepitaxial SrRuO3 on (001) SrTiO3. Applied Physics Letters 79, 1447-1449, doi:doi:http://dx.doi.org/10.1063/1.1389837 (2001).) In addition, these PLD grown films show a RHEED signature corresponding to the transition from RuO₂ termination to SrO termination. (See, Rijnders, G., Blank, D. H. A., Choi, J. & Eom, C. B. Enhanced surface diffusion through termination conversion during epitaxial SrRuO₃ growth. Applied Physics Letters 84, 505-507, doi:Doi 10.1063/1.1640472 (2004).) This change in termination was also observed in sputter grown SRO films, as seen in the inset of FIG. 3A. The elongated first unit cell oscillation of approximately 38 seconds was nearly double the steady state average of 19.3 seconds per unit cell and corresponds to the transition from BO₂ termination to AO termination. However, in contrast to PLD growth, the SRO did transition from layer-by-layer to step flow growth. FIG. 3A shows RHEED oscillations characteristic of layer-by-layer growth with each oscillation corresponding to one unit cell. If the growth mode were to have transitioned to step flow, the oscillations would have died out. The oscillations were observed out to greater than 50 unit cells, clearly establishing the ability to have layer-by-layer control over sputter grown SRO films. Due to the transition in growth mode of PLD grown SRO, layer-by-layer control out to many unit cells has not been demonstrated in PLD, giving sputtering better thickness control over SRO films.

To further demonstrate the capability of this technique, these films were grown without presputtering in order to observe the time necessary to reach steady state. An asymmetric double sigmoidal fit of the oscillations is shown in FIG. 3A starting with the first complete peak. This fit was used to obtain the crest to crest period of each oscillation, or the time required for each successive unit cell, which is shown in FIG. 3B. From this plot it was observed that unit cell growth rate started near 21 seconds per unit cell and relaxed down to the steady state period of approximately 19.3 seconds after 15 unit cells. An exponential decay was fit to these data to better show the convergence to the steady state deposition rate. From this the minimum presputter time can be determined but it can also be observed that it is a non-uniform growth rate throughout, indicating that without the use of an in situ monitoring technique precise unit cell control may not be possible.

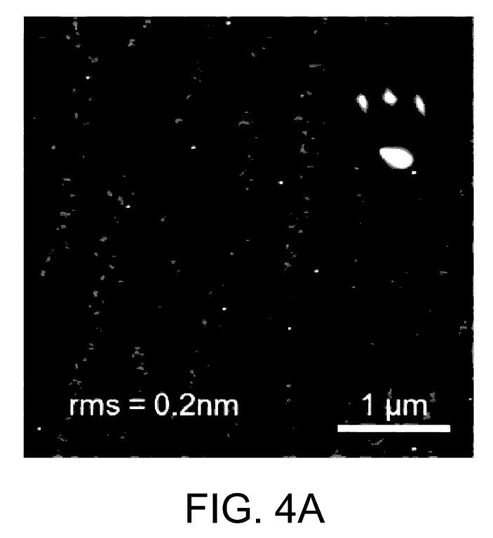

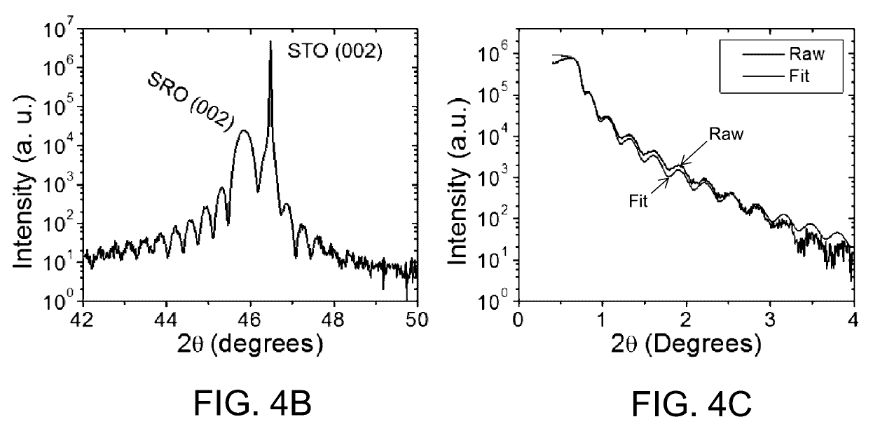

The RHEED image of the 27.1 nm SRO film after the growth is seen in the inset of FIG. 4A. This image was taken in vacuum with the magnetic field from the sputter source still present, which is evident by the tilted pattern. Clear diffracted and specular spots can be observed with minimal streaking suggesting high crystallinity and a predominantly two-dimensional surface. Ex situ analysis of the SRO film structure and thickness was carried out with x-ray diffraction (XRD) and x-ray reflectivity (XRR) respectively and the surface morphology was characterized by atomic force microscopy (AFM), as seen in FIG. 4. The AFM image in FIG. 4A shows clear terrace structures; however, the steps do not have linear and smooth edges, and show some small single unit cell islands on the terraces. This is comparable to SRO films grown on STO by PLD, but the existence of the small islands on the sputter grown film may be an indication of nucleation sites corresponding to the layer-by-layer growth as opposed to the step flow growth of PLD. The AFM result also corroborated observations from the RHEED pattern that the film surface was very smooth.

The out of plane XRD scan seen in FIG. 4B shows the relationship of the (002) SRO film peak to the STO (002) substrate peak. Clear Kiessig Fringes can be seen, which indicate a smooth surface and interface. The rocking curve of the (002) SRO peak has a FWHM of 0.024° indicating low mosaic spread and high crystalline quality. These ex situ measurements confirm what has already been observed in situ with RHEED, demonstrating the power and efficiency of real-time monitoring.

The XRR data and corresponding fit can be seen in FIG. 4C with the raw data and the fitted data. Using the fit, an accurate total thickness of the film was found to be 27.1 nm from which a growth rate of 20.1 seconds per unit cell was derived. When compared to the 19.3 seconds per unit cell steady state rate acquired from the RHEED oscillations it can be seen that these results are in close agreement. However, from the varying period of the oscillations seen in FIG. 2D it is clear that using RHEED is a more robust and reliable way of ensuring precise unit cell control compared with a time based calibration. Additionally, these results confirm that the SRO grows in a layer-by-layer mode because one would expect these values to be significantly different if there was also a step flow contribution to the growth. This is a clear indication that each RHEED oscillation corresponds to exactly one unit cell being deposited on the sample surface, and as such, is believed to be the first demonstration by any growth method of greater than 50 RHEED oscillations providing digital control during SRO growth.

### Discussion

Combining sputter deposition with in situ RHEED is inherently a challenging task due to the strong magnetic fields and high pressures that adversely affect the electron beam. Moreover, unlike PLD and MBE which have semi-standardized growth geometries, sputtering covers a wide range of arrangements from on-axis to 90° off-axis and everything in between. This creates a problem when attempting to predict the magnetic field effects on the RHEED electron beam in an ever changing layout. With this in mind a model in COMSOL was built to simulate nearly any setup and to help find a solution that minimized the bending of the electron beam. By using the COMSOL model to account for the bending and by considering the effect of gas scattering clear diffraction patterns of a SrTiO₃ substrate in a sputtering environment were obtained.

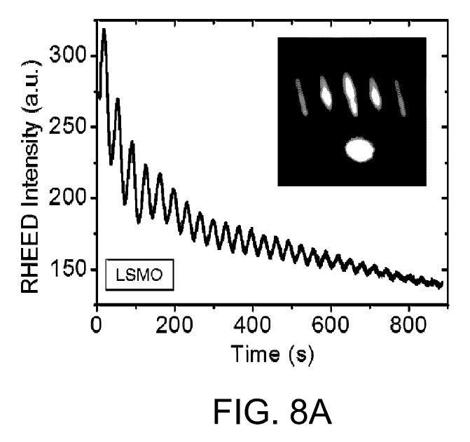

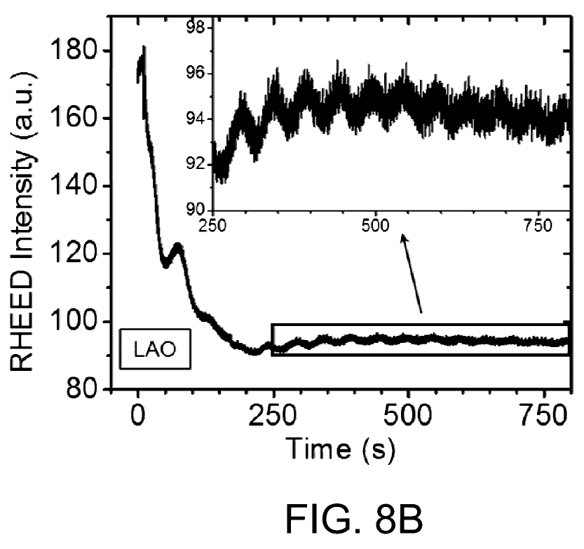

This example presents the first demonstration of specular spot intensity oscillations associated with layer-by-layer growth during sputter growth. In addition, it presents extended specular spot oscillations during SrRuO₃ deposition which has not been seen in PLD growth. This technique has also been extended to LSMO and LAO films as seen in FIG. 8A and FIG. 8B, respectively, where clear RHEED oscillations can be seen during the growth of both films demonstrating that this technique is applicable to many oxide materials.

Methods

COMSOL Modeling

The simulation was created using COMSOL Multiphysics, AC/DC Module, and Particle Tracing Module. The geometry of the chamber was created in SolidWorks and imported into COMSOL. The electron gun, phosphor screen, and heater were simulated as Type 316 steel, with relative permeability of 1. The magnets were modeled with a relative permeability of 1.05 and a remnant flux density of 1.201 T. All of the remaining volume was simulated as a low pressure gas with relative permeability of 1. The particles in the beam were given the mass and charge of an electron, and 25 particles were released from a 1 mm wide aperture with a velocity corresponding to 35 keV of kinetic energy. The particle beam experienced a magnetic force from the magnets once the particles were released. A mesh was created for the entire geometry and then a time dependent study was performed. Post processing included coloring the north and south ends of each magnet and showing the beam path via colors corresponding to the magnetic force exerted on the beam at each point. A vector field showing the magnetic field strength and direction was also created. After post processing, camera views were chosen to export the proper 2D images for use as figures.

Film Growth

All films discussed in this work were grown with one, 2-inch sputter source present in a 90° off-axis geometry. The working distances were fixed at 2.5 inches from the center of the sputter gun to the face of the heater and 1.5 inches from the center of the heater to the face of the gun. These are the same dimensions as used in the COMSOL model. The films were all grown on TiO₂ terminated STO (001) substrates which show sharp step and terrace structures. The sputtered SrRuO₃ thin films were grown at 590° C. with a working pressure of 200 mTorr. The gas ratio for this growth was 12:8 Ar to O₂ respectively and a stoichiometric ceramic target was used. The La₁₋ₓSrₓMnO₃ was grown at 700° C. in a 200 mTorr gas environment of 19:1 sccm of Ar to O₂ from a stoichiometric ceramic LSMO target. The LaAlO₃ films were grown following published conditions shown to produce a conducting interface. (See, Podkaminer, J. P. et al. Creation of a two-dimensional electron gas and conductivity switching of nanowires at the LaAlO3/SrTiO3 interface grown by 90° off-axis sputtering. Applied Physics Letters 103, -, doi:doi:http://dx.doi.org/10.1063/1.4817921 (2013).) These films were grown from a stoichiometric single crystal target. The LSMO and LAO films grow in the layer-by-layer growth mode as demonstrated by the RHEED oscillations in FIG. 8.

### Example 2

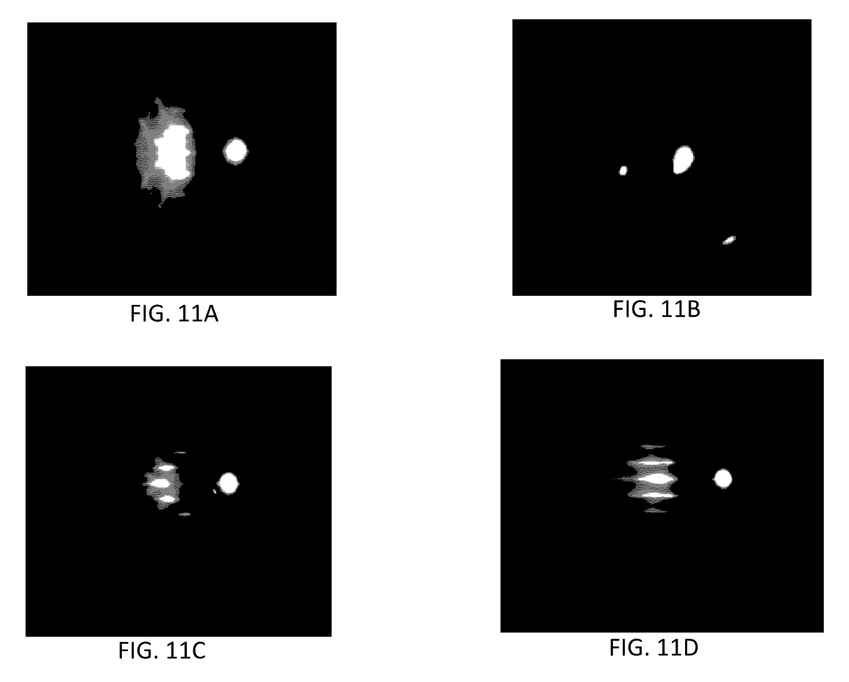

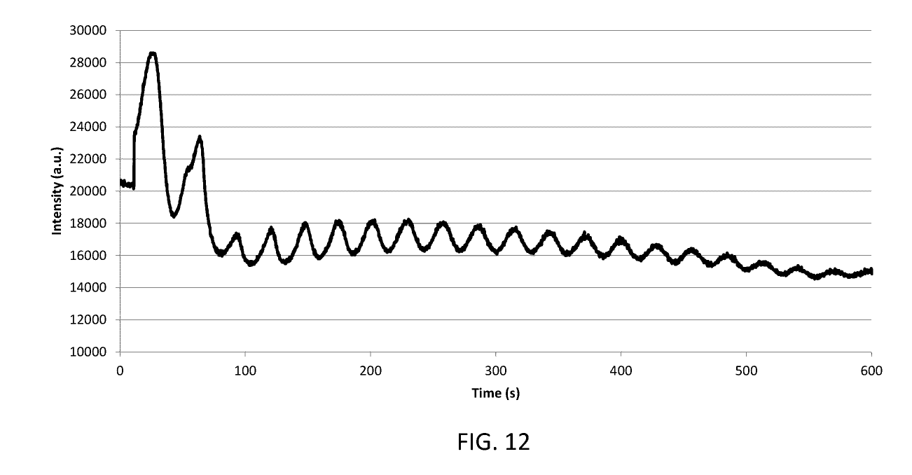

As a demonstration, a dummy magnet assembly was built to simulate the magnetic field from a magnetron sputtering gun and was used in the growth chamber to create the effect of a dual sputtering guns with antisymmetric magnetic polarizations. In this setup, one real sputtering gun was present, with the dummy magnet assembly disposed opposite the real sputtering gun in a 90° off-axis sputtering geometry. The difference between the diffraction pattern for the single sputtering gun setup and the antisymmetric dual gun setup is shown in FIGS. 11A, 11B, and 11C. FIG. 11A shows a STO substrate in vacuum without the effect of any magnetic field. Clear diffraction spots were observed with strong Kikuchi lines. FIG. 11B shows the diffraction pattern resulting from the single gun setup with the clear tilting of the pattern and reduction in sharpness. FIG. 11C is the diffraction pattern observed with the antisymmetric dual sputtering gun setup. No tilting of the electron beam was observed. The pattern is sharp and shows Kikuchi lines similar to the pattern seen in FIG. 11A, with some slight elongation of the spots. Using this setup SRO was grown on the STO substrate and clear RHEED oscillations were observed, as seen in FIG. 12, demonstrating the ability to achieve layer-by-layer control of film growth. The resulting RHEED pattern following the growth is shown in FIG. 11D, with a very strong specular spot present and Kikuchi lines still visible, indicating a very sharp and smooth surface.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more”.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method of depositing and monitoring the growth of a film of material on the surface of a substrate using a magnetron sputtering and RHEED system that comprises:
(a) a substrate having a surface;
(b) a first magnetron sputter gun comprising a first magnet assembly and a first layer of target material over the first magnet assembly, the first layer of target material having a first target surface, wherein the surface of the substrate and the first target surface are arranged in an off-axis geometry;
(c) a second magnetron sputter gun disposed symmetrically opposite and facing the first magnetron sputter gun, the second magnetron sputter gun comprising a second magnet assembly and a second layer of target material over the second magnet assembly, the second layer of target material having a second target surface, wherein the surface of the substrate and the second target surface are arranged in an off-axis geometry;
(d) an RHEED electron gun configured to direct a beam of electrons onto the surface of the substrate at a glancing angle, such that the beam of electrons is directed symmetrically between the first target surface and the second target surface; and
(e) a RHEED screen disposed opposite the RHEED electron gun and configured to detect electrons forward scattered from the surface of the substrate;
the method comprising:
(i) applying antisymmetric magnetic polarizations to the first magnet assembly and the second magnet assembly;
(ii) growing a film of material on the surface of the substrate by sputtering target material from at least one of the first and second layers of target material onto the surface of the substrate via magnetron sputtering;
(iii) directing a beam of electrons from the RHEED electron gun onto the surface of the substrate; and
(iv) recording a diffraction pattern for electrons reflected from the surface of the substrate onto the RHEED screen, in real-time while the film of material is being grown.

2. The method of claim 1, wherein the surface of the substrate and the first target surface are arranged in a 90° off-axis geometry and the surface of the substrate and the second target surface are arranged in a 90° off-axis geometry.

3. The method of claim 2, wherein the first and second magnetron sputter guns are the only magnetron sputter guns in the magnetron sputtering and RHEED system, and further wherein the RHEED electron gun is configured to direct the beam of electrons onto the surface of the substrate at a glancing angle, such that the beam of electrons is centered between the plane of the first target surface and the plane of the second target surface.

4. The method of claim 2, wherein the distance between the surface of the substrate and the first and second magnet assemblies is not greater than 8 cm.

5. The method of claim 4, wherein the method is carried out in a sputtering chamber at a chamber pressure of at least 100 mTorr.

6. The method of claim 2, wherein the method is carried out in a sputtering chamber at a chamber pressure of at least 50 mTorr.

7. The method of claim 2, wherein the method is carried out in a sputtering chamber at a chamber pressure of at least 200 mTorr.

8. The method of claim 2, wherein the magnetron sputtering and RHEED system further comprises:
(f) a third magnetron sputter gun comprising a third magnet assembly and a third layer of target material over the third magnet assembly, the third layer of target material having a third target surface, wherein the surface of the substrate and the third target surface are arranged in a 90° off-axis geometry; and
(g) a fourth magnetron sputter gun disposed symmetrically opposite and facing the third magnetron sputter gun, the fourth magnetron sputter gun comprising a fourth magnet assembly and a fourth layer of target material over the fourth magnet assembly, the fourth layer of target material having a fourth target surface, wherein the surface of the substrate and the fourth target surface are arranged in a 90° off-axis geometry;
wherein the RHEED electron gun is configured to direct the beam of electrons onto the surface of the substrate at a glancing angle, such that the beam of electrons goes through a central axis about which the first, second, third and fourth target surfaces are symmetrically arranged.

9. The method of claim 2, wherein the first layer of target material comprises a different target material than the second layer of target material.

10. The method of claim 8, wherein the first layer of target material comprises a different target material than the second layer of target material, and further wherein the third layer of target material comprises a different target material than the fourth layer of target material.

11. The method of claim 1, wherein the incident beam of electrons from the RHEED is offset from center in the x-direction and a magnetic field generated by the first and second magnet assemblies deflects the beam of electrons back towards the x-direction center of the RHEED screen.

12. A method of aligning a RHEED electron beam in a magnetron sputtering and RHEED system that comprises:
(a) a first magnetron sputter gun comprising a first magnet assembly comprising: a first central magnet and a first annular magnet disposed around the first central magnet; and a first layer of target material over the first magnet assembly;
(b) a second magnetron sputter gun disposed symmetrically opposite and facing the first magnetron sputter gun, the second magnetron sputter gun comprising: a second magnet assembly comprising: a second central magnet and a second annular magnet disposed around the second central magnet; and a second layer of target material over the second magnet assembly;
(c) a RHEED electron gun configured to generate a beam of electrons; and
(d) a RHEED screen disposed opposite the RHEED electron gun, wherein the RHEED electron gun is configured to direct the beam of electrons toward the RHEED screen;
the method comprising:
(i) applying antisymmetric magnetic polarizations to the first magnet assembly and the second magnet assembly, such that the north poles of the first and second annular magnets face toward the positive x-direction and the north poles of the first and second central magnets face toward the negative x-direction;
(ii) directing a beam of electrons from the RHEED electron gun toward the RHEED screen, such that the beam of electrons travels below the first and second layers of target material, but between the plane of the first target surface and the plane of the second target surface, whereby a magnetic field generated by the first and second magnet assemblies deflects the beam of electrons away from the x-direction center of the RHEED screen when the RHEED gun is not properly aligned in the x-direction;
(iii) moving the electron gun in the x-direction and monitoring the x-direction displacement of the beam of electrons on the RHEED screen; and
(iv) positioning the RHEED gun at a location in the x-direction that minimizes or eliminates the x-direction displacement of the beam of electrons on the RHEED screen.
